(19) United States
(12) Patent Application Publication
(10) Pub. No.: US 2014/0008248 A1
(43) Pub. Date: Jan. 9, 2014

(54) CASE APPARATUSES FOR PORTABLE ELECTRONIC DEVICES

(71) Applicant: Targus Group International, Inc., Anaheim, CA (US)

(72) Inventor: Mark Thoni, Rancho Santa Margarita, CA (US)

(21) Appl. No.: 13/937,027

(22) Filed: Jul. 8, 2013

Related U.S. Application Data
(60) Provisional application No. 61/668,881, filed on Jul. 6, 2012.

(51) Int. Cl. H05K 5/00

(52) U.S. Cl. CPC H05K 5/0086
USPC 206/37

(57) ABSTRACT

A case for a portable electronic devices such as smart phones includes upper and lower shells that are joined by elastic members. The upper shell includes a base surface and sidewalls to retain a portion of the portable electronic device and, likewise, the lower shell includes a base and sidewalls to retain a portion of the portable electronic device. The elastic members enable separation of the upper and lower shells to permit insertion of the portable electronic device and further provide biasing to move the shells together and retain the portable electronic device.

### RELATED APPLICATIONS

This application claims the benefit under 35 U.S.C. §119(e) of U.S. Provisional Patent Application No. 61/668,881, filed Jul. 6, 2012, and entitled “CASE APPARATUSES FOR PORTABLE ELECTRONIC DEVICES,” which is hereby incorporated by reference herein in its entirety.

### TECHNICAL FIELD

The present disclosure relates generally to portable electronic devices and, more specifically, to case accessories for portable electronic devices.

### BRIEF DESCRIPTION OF THE DRAWINGS

The written disclosure herein describes illustrative embodiments that are non-limiting and non-exhaustive. Reference is made to certain of such illustrative embodiments that are depicted in the figures, in which:

FIGS. 1A and 1B illustrate perspective views of an embodiment of a case for a portable electronic device consistent with embodiments of the present disclosure;

FIGS. 2A and 2B illustrate perspective views of an embodiment of a case with a portable electronic device stored within consistent with embodiments of the present disclosure;

FIGS. 3A and 3B illustrate plan views of an embodiment of a case for a portable electronic device consistent with embodiments of the present disclosure;

FIGS. 4A and 4B illustrate perspective views of an alternative embodiment of a case for a portable electronic device consistent with embodiments of the present disclosure;

FIGS. 5A and 5B illustrate perspective views of an alternative embodiment of a case with a portable electronic device stored within consistent with embodiments of the present disclosure;

FIGS. 6A and 6B illustrate plan views of an alternative embodiment of a case for a portable electronic device consistent with embodiments of the present disclosure;

FIG. 7 illustrates a perspective view of an embodiment of a case for a portable electronic device in a display configuration consistent with embodiments of the present disclosure; and

FIG. 8 illustrates a plan view of an embodiment for a case for a portable electronic device.

### DETAILED DESCRIPTION

The proliferation of portable electronic devices (PEDs), including notebook and tablet computers (e.g., the Apple® iPad® and Samsung® Galaxy®), portable digital assistants (PDAs), an electronic book reader (e.g., the Amazon® Kindle® and smartphones (e.g., the Apple® Phone®, Google® Android®), has placed more computing power into the hands of users than the computing power of early computers that occupied an entire room. This portable computing power has enhanced both personal and business mobile productivity. Due to their portability, however, PEDs may be susceptible to damage and protecting an expensive electronic device is a priority to the user. Embodiments of the present disclosure provide an accessory case for a PED configured to protect the PED from damage. In various embodiments, the case may be configured to enclose and protect the PED in a closed position and support the PED upright and/or elevated (i.e., propped up) in an open position.

Embodiments may be best understood by reference to the drawings. It will be readily understood that the components of the present disclosure, as generally described and illustrated in the drawings herein, could be arranged and designed in a wide variety of different configurations. Thus, the following more detailed description of the embodiments of the apparatus is not intended to limit the scope of the disclosure, but is merely representative of possible embodiments of the disclosure. In some cases, well-known structures, materials, or operations are not shown or described in detail. The case embodiments disclosed herein may include any number of buttons, apertures, grooves, slots, and the like to enable interaction, access, and viewing with corresponding input and output devices of a PED.

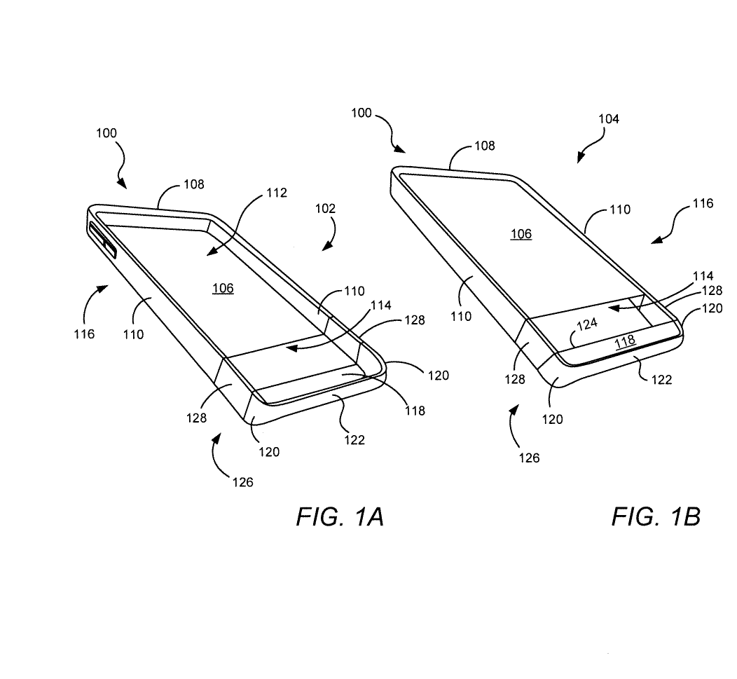

FIGS. 1A and 1B illustrate a case 100 for a PED (not shown) that is configured to receive the PED and retain, protect, carry, and secure the PED. FIG. 1A is referred to herein as the front side 102 which receives the PED and FIG. 1B is the back side 104. As used herein, the PED may be any portable electronic device including, for example, a notebook computer, an electronic book reader (e.g., the Amazon® Kindle®), a smartphone (e.g., the Apple® iPhone®, the Motorola® Droid®, and the BlackBerry® Storm®) and/or a tablet computer (e.g., the Apple® iPad®, the HP® Slate, and the Samsung® Galaxy® Tablet). The PED may include on the front and/or the back face of the PED a display that is viewable in either a portrait orientation or a landscape orientation, a user input, and a data input/output port. In some embodiments, the case 100 may be configured such that the display, user input, and data input/output port are accessible by a user of the PED while the PED is disposed in the case 100. Access may be provided by apertures or buttons, toggles, switches and the like which interact with corresponding PED controls. Further, in some embodiments, the case 100 may include a protective display disposed over the PED display.

The case 100 comprises a primary base surface 106 to support a backside of a PED and may define a generally rectangular shape, include a substantially planar member, may further include rounded corners, and may include one or more apertures for accessing the PED and/or to enable camera operation. In one embodiment, the primary base surface 106 covers a majority of a backside of a PED.

The case 100 includes a top wall 108 extending from a side of the primary base surface 106 which is intended to cover a top wall of a PED. Two primary sidewalls 110 extend from the primary base surface 106 and are substantially parallel to one another. Together, the sidewalls 108, 110 and the base surface 106 define a recess 112 to receive a PED. The sidewalls 108, 110 may be configured with apertures, grooves, switches, buttons, toggles, or the like to allow access to the PED. The sidewalls 108, 110 may define a frame or window at least partially extending over the recess 112 to retain the PED while still allowing access to a PED. In one embodiment, the opposing and parallel sidewalls 110 may include a configuration or material to facilitate gripping of the case 100. For example, the sidewalls 110 may include a semi-rigid and compressible material.

A fourth side 114 of the primary base surface 106 may not have a corresponding, extending sidewall and is designated the access side 114. The primary base surface 106 and the sidewalls 108, 110 are designated herein as the primary case member 116.

The case 100 may include a secondary base surface 118 with a planar surface which supports a minority of a backside of a PED. The secondary base surface 118 may also define a substantially rectangular shape with rounded corners. The case 100 includes secondary sidewalls 120 and a bottom wall 122 which extend from the secondary base surface 118. The walls 120, 122 may include one or more apertures to enable access to the PED. In an alternative embodiment, the case 100 may not have a secondary base surface 118 but would still include the walls 120, 122.

A fourth side 124 of the secondary base surface 118 designated herein as the secondary access side, does not have a corresponding sidewall. The secondary base surface 118 and the secondary walls 120, 122 are collectively referred to herein as the secondary case member 126. The primary and secondary case members 116, 126 may comprise various semi-rigid and/or rigid materials.

Two opposing stretchable strips 128 are coupled to the two parallel primary sidewalls 110 and two parallel secondary sidewalls 120. The strips 128 may include any one of various elastic materials known in the art. The strips 128 may be coupled to the primary and secondary walls 110, 120 adjacent the primary and secondary access sides 114, 124. The strips 128 provide sufficient strength to pull the primary and secondary case members 116, 126 together adjacent one another in a closed configuration. In the closed configuration, the base surfaces 106, 118 form a continuous planar member 106, 118 to support the PED and the PED is contained within the walls 108, 110, 120, 122.

In one embodiment, the primary and secondary base surfaces 106, 118 are configured with tongue and groove features to facilitate alignment of the base surfaces one another.

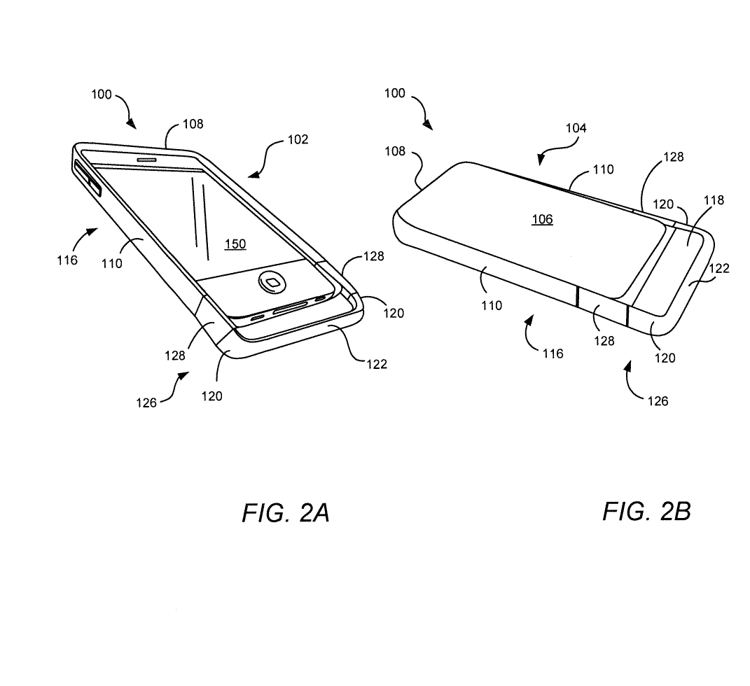

Referring to FIGS. 2A and 2B, the case 100 is shown with a PED 150. FIG. 2A illustrates the front side 102 of the case 100 and FIG. 2B illustrates a back side 104 of the case 100. In inserting a PED 150 into the case 100, a user applies tension to the strips 128 to separate the primary and secondary case members 116, 126 away from one another in an open configuration. The PED 150 is inserted through the access side 114 into the recess 112 defined by the primary base surface 106 and primary walls 108, 110. A user then releases tension on the strips 128 and the secondary base surface 118 and secondary sidewalls 120, defining a secondary recess, receive a portion of the PED 150. Thus inserted, the backside and sidewalls of the PED 150 are protected and a PED display is accessible.

In transitioning from a closed configuration to an open configuration, a user may apply tension to the strips 128 to separate the primary and secondary case members 116, 126. A user may then extract the PED 150 from the case 100. Alternatively, a user may remove the secondary case member 126 to expose a side of the PED 150 while the primary case member 116 continues to retain a portion of the PED 150. A user may thereby access a port on the exposed side to enable access such as for charging and/or data synchronization.

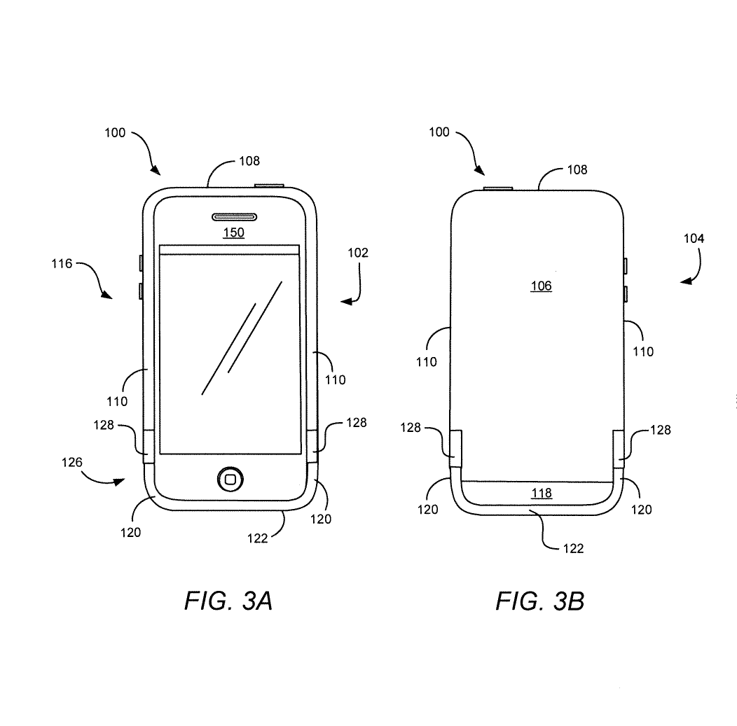

Referring to FIGS. 3A and 3B, front and back sides 102, 104 of the case 100 are shown in a closed configuration with a PED 150 retained within. As illustrated, the PED display is accessible while the sides and back of the PED 150 are protected by the case 100.

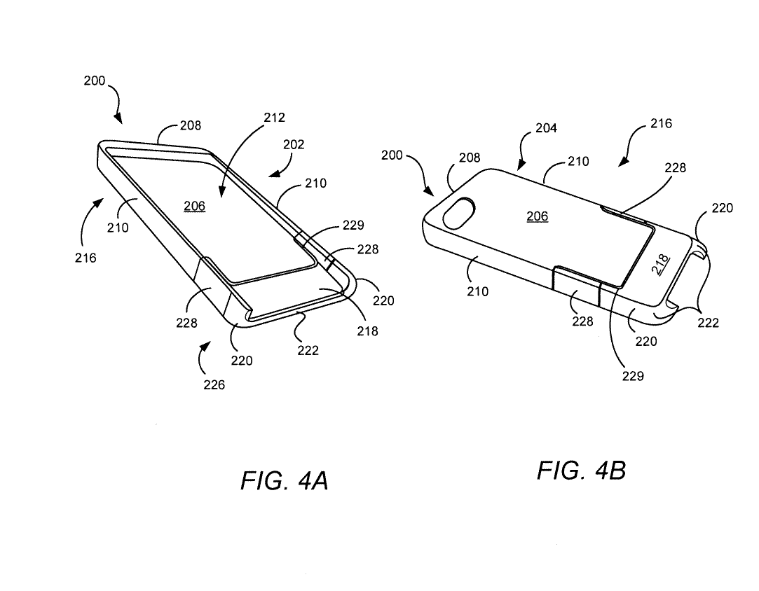

Referring to FIGS. 4A and 4B, perspective views of an alternative embodiment of a case 200 is shown for a PED. FIG. 4A is referred to herein as the front side 202 which allows access to a PED display and FIG. 2B is the back side 204. As in other embodiments, the case 200 may be configured such that the display, user input, and data input/output port are accessible by a user of the PED while the PED is disposed in the case 200. Access may be provided by apertures or buttons, toggles, switches and the like which interact with corresponding PED controls.

The case 200 comprises a primary base surface 206 to support a majority of a backside of a PED and may define a generally rectangular shape, include a substantially planar member, may further include rounded corners, and may include one or more apertures for accessing the PED and/or to enable camera operation. The case 200 includes a top wall 208 and two primary sidewalls 210, substantially parallel to one another, extending from sides of the primary base surface 206 as shown. The walls 208, 210 and the primary base surface 206 define a recess 212 to receive a PED. The walls 208, 210 may be configured with apertures, grooves, buttons, switches, toggles, and the like to access or interact with the PED. The walls 208, 210 may define a frame or window at least partially extending over the recess 212 to retain the PED while still allowing access to a PED.

A fourth side 214 of the primary base surface 206 may not have a corresponding, extending sidewall and is designated the access side 214. The primary base surface 206 and the walls 208, 210 are designated herein as the primary case member 216. The primary base surface 206 may have a greater length than the sidewalls 210 and may therefore extend without corresponding sidewalls 210.

The case 200 includes a secondary base surface 218 with a planar surface which supports a minority of a PED backside. The secondary base surface 218 may also define a substantially rectangular shape with rounded corners. The case 200 includes secondary sidewalls 220 and a bottom wall 222 which extend from the secondary base surface 218. In one embodiment, the bottom wall 222 may only partially extend along the corresponding side of the secondary base surface 218 to thereby allow access to a power and data synchronization port of a PED. As illustrated, the bottom wall 222 extends for a minority of the length of the corresponding side.

The walls 220, 222 may include one or more apertures, switches, toggles, buttons, and the like to enable access to the PED. A fourth side 224 of the secondary base surface 218, designated herein as the secondary access side, does not have a corresponding sidewall. The secondary base surface 218 and the secondary walls 220, 222 are collectively referred to herein as the secondary case member 226.

Two opposing flexible strips 228 are coupled to the two parallel primary sidewalls 210 and two parallel secondary sidewalls 220. The strips 228 may include any one of various pliable or elastic materials known in the art. With the application of pressure, the strips 228 provide pivotable separation of the case members 216, 226 from one another to an open configuration wherein a PED may be inserted into the recess 212. Without pressure, the strips 228 return to the original, closed configuration wherein the base surfaces 206, 218 are disposed adjacent one another to support a back side of a PED. In the closed configuration, the base surfaces 206, 218 may be separated from one another by a groove 229 which may also partially extend along opposing sides of the primary base surface 206. The groove 229 provides unobstructed separation of the case members 216, 226 as the members pivot relative to one another.

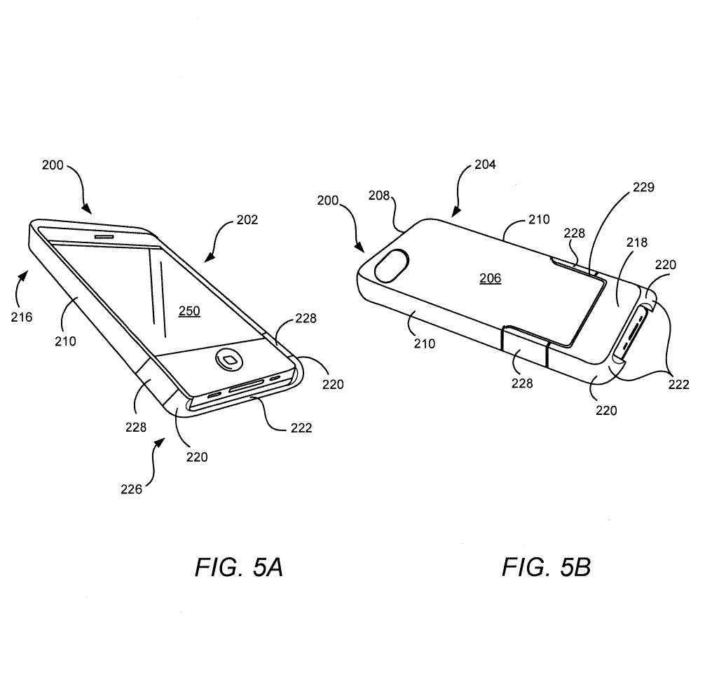

Referring to FIGS. 5A and 5B, the case 200 is shown in an open configuration with a PED 250. FIG. 2A illustrates the front side 202 of the case 200 and FIG. 2B illustrates a back side 204 of the case 200. In inserting a PED 250 into the case 200, a user applies pressure to the strips 228 to separate the primary and secondary case members 216, 226 away from one another. The PED 250 is inserted through the access side 214 into the recess 212 defined by the primary base surface 206 and primary walls 208, 210. A user then releases pressure on the strips 228 and the secondary base surface 218 and secondary sidewalls 220, defining a secondary recess, receive a portion of the PED 250.

In transitioning from a closed configuration to an open configuration, a user may apply pressure to the strips 228 to separate the primary and secondary case members 216, 226. A user may then extract the PED 250 from the case 200. The open configuration may also be used to allow access to a port on a bottom side of the PED 250 which is appreciated in an embodiment where the bottom wall 222 would prevent access.

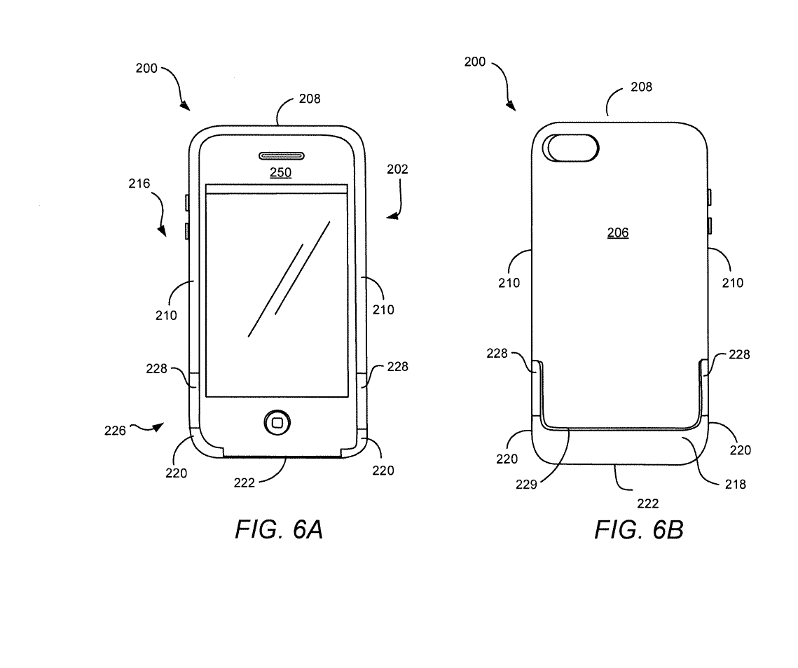

Referring to FIGS. 6A and 6B, front and back sides 202, 204 of the case 200 are shown in a closed configuration with a PED 250 retained within. As illustrated, the PED display is accessible while the sides and back of the PED 250 are protected by the case 200.

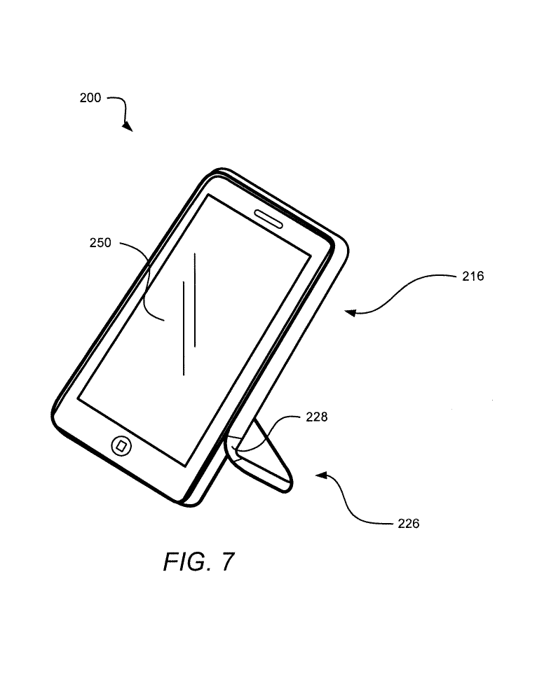

Referring to FIG. 7, a perspective view of the case 200 of FIGS. 4A-6B is shown in an open configuration with the flexible strips 228 providing separation of the primary and secondary case members 216, 226 relative to one another. The case 200 also provides a display configuration with the PED 250 and the secondary case member 216 resting on a horizontal surface to provide angled viewing of the PED 250. The primary case member 216 secures the PED 250 while the secondary case member 226 provides an angled support.

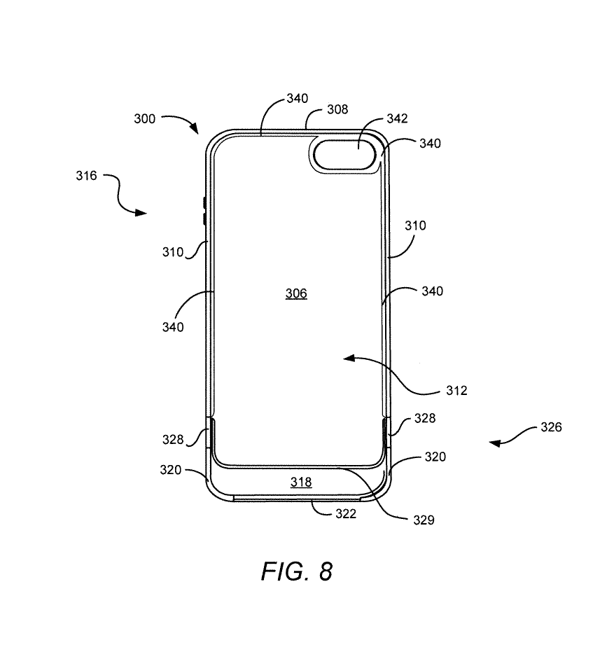

Referring to FIG. 8, a plan view of a case 300 is shown with the front side exposed. As in previous embodiments, the case 300 includes a primary base surface 306, top side wall 308, primary sidewalls 310, primary recess 312, primary case member 316, secondary base surface 318, secondary sidewalls 320, bottom wall 322, secondary case member 326, and flexible strips 328. The case 300 further includes sliders 340 that may be disposed on the primary base surface 306 to facilitate insertion of a PED into the recess 312 and reduce scratching of the PED. The sliders 340 further protrude from the base surface 306 and provide suspension of the PED once the PED is secured in the case 300 to enhance cushioning and protection. The sliders 340 may comprise an elastomeric material including thermoplastic elastomers (TPE), thermal plastic urethane (TPU), polyurethane, transpolyurethane, unsaturated and saturated rubbers, and the like.

A slider 340 may extend around the majority or the entirety of the border between the primary base surface 306 and the walls 308, 210. A slider 340 may be a single continuous member or may be disposed at discreet locations. For example, sliders 340 may only be disposed along the borders between the primary base surface 306 and the sidewalls 310. A slider 340 may also extend around an aperture 342, in the illustrated example a camera aperture, to provide cushioned support for the PED. One or more sliders 340 may also be disposed on the walls 308, 310 to facilitate insertion and removal of the PED and cushioned support of the PED.

The cases disclosed herein provide separation of primary and secondary case members while still retaining connection between the case members. The primary and secondary case members define respective recesses to receive and support portions of a PED. The primary and secondary case members may also be referred to as primary and secondary shells.

It will be understood by those having skill in the art that changes may be made to the details of the above-described embodiments without departing from the underlying principles presented herein. In addition, any suitable combination of various embodiments, or the features thereof, is contemplated. Further, any methods disclosed herein may comprise one or more steps or actions for performing the described method. These method steps and/or actions may be interchanged with one another. In other words, unless a specific order of steps or actions is required for proper operation of the embodiment, the order and/or use of specific steps and/or actions may be modified.

Throughout this specification, any reference to “one embodiment,” “an embodiment,” or “the embodiment” means that a particular feature, structure, or characteristic described in connection with that embodiment is included in at least one embodiment. Thus, the quoted phrases, or variations thereof, as recited throughout this specification are not necessarily all referring to the same embodiment. Similarly, it should be appreciated that in the above description of embodiments, various features are sometimes grouped together in a single embodiment, figure, or description thereof for the purpose of streamlining the disclosure. This method of disclosure, however, is not to be interpreted as reflecting an intention that any claim require more features than those expressly recited in that claim. Rather, inventive aspects lie in a combination of fewer than all features of any single foregoing disclosed embodiment. It will be apparent to those having skill in the art that changes may be made to the details of the above-described embodiments without departing from the underlying principles set forth herein.

What is claimed is:

1. A case for a portable electronic device, comprising:
a primary case member including,
a primary base surface,
first and second substantially parallel, primary sidewalls extending from the primary base surface and defining a primary recess to receive at least a portion of the portable electronic device;
a secondary case member including,
a secondary base surface,
first and second substantially parallel, secondary sidewalls extending from the secondary base surface and defining a secondary recess to receive at least a portion of the portable electronic device; and
first and second flexible strips coupled to the corresponding primary and secondary sidewalls.

2. The case of claim 1, wherein the secondary case member further includes a secondary base surface coupled to the first and second secondary sidewalls and together defining a secondary recess to receive at least a portion of the portable electronic device, wherein the first and second flexible strips are configured to bias the primary and secondary base surfaces into a planar configuration relative to one another, and, upon application of force, the first and second flexible strips are further configured to pivot the primary and secondary base surfaces into a non-planar configuration.

3. The case of claim 2, wherein the primary and secondary base surfaces define a gap when disposed in a planar configuration.

4. The case of claim 3, wherein the gap includes a first portion extending substantially parallel to the first primary sidewall, a second portion extending substantially orthogonal to the first portion, and a third portion extending substantially parallel to the second primary sidewall.

5. The case of claim 1, wherein the primary base surface is configured to support a majority of a base surface of the portable electronic device.

6. The case of claim 1, wherein the primary case member includes a top wall coupled to the primary sidewalls and the secondary case member includes a bottom wall coupled to the secondary sidewalls.

7. The case of claim 6, wherein the bottom wall partially extends along a corresponding bottom side of the secondary case member.

8. The case of claim 1, further comprising a first slider protrusion disposed on the primary base surface.

9. The case of claim 8, wherein the first slider protrusion is further disposed adjacent the first primary sidewall and further comprising a second slider protrusion disposed on the primary base surface adjacent the second primary sidewall.

10. A case for a portable electronic device, comprising:
a primary case member including,
a primary base surface,
first and second substantially parallel, primary sidewalls extending from the base surface and defining a primary recess to receive at least a portion of the portable electronic device;
a secondary case member including,
a secondary base surface,
first and second substantially parallel, secondary sidewalls extending from the secondary base surface and defining a secondary recess to receive at least a portion of the portable electronic device; and
first and second elastic strips coupled to the primary and secondary sidewalls and configured to bias the primary and secondary case members towards one another and, upon application of force, separate the primary and secondary case members from one another.

11. The case of claim 10, wherein the primary base surface is configured to support a majority of a base surface of the portable electronic device.

12. The case of claim 10, wherein the primary case member includes a top wall coupled to the primary sidewalls and the secondary case member includes a bottom wall coupled to the secondary sidewalls.

13. The case of claim 12, wherein the bottom wall partially extends along a corresponding bottom side of the secondary case member.

14. The case of claim 10, further comprising a first slider protrusion disposed on the primary base surface.

15. The case of claim 14, wherein the first slider protrusion is further disposed adjacent the first primary sidewall and further comprising a second slider protrusion disposed on the primary base surface adjacent the second primary sidewall.

16. A case for a portable electronic device, comprising:
a primary case member including,
a primary base surface,
first and second substantially parallel, primary sidewalls extending from the base surface and defining a primary recess to receive at least a portion of the portable electronic device;
a secondary case member including, first and second substantially parallel, secondary sidewalls;
first and second flexible strips coupled to the primary and secondary sidewalls; and
a slider protrusion disposed on the primary base surface.

17. The case of claim 16, wherein the slider protrusion is further disposed adjacent the first primary sidewall and further comprising a second slider protrusion disposed on the primary base surface adjacent the second primary sidewall.

18. The case of claim 16, wherein the secondary case member further includes a secondary base surface coupled to the first and second secondary sidewalls and together defining a secondary recess to receive at least a portion of the portable electronic device, wherein the first and second flexible strips are configured to bias the primary and secondary base surfaces into a planar configuration relative to one another, and, upon application of force, the first and second flexible strips are further configured to pivot the primary and secondary base surfaces into a non-planar configuration.

19. The case of claim 18, wherein the primary and secondary base surfaces define a gap when disposed in a planar configuration.

20. The case of claim 19, wherein the gap includes a first portion extending substantially parallel to the first primary sidewall, a second portion extending substantially parallel to the bottom wall, and a third portion extending substantially parallel to the second primary sidewall.
